(19) United States
(12) Patent Application Publication
(10) Pub. No.: US 2017/0315596 A1
(43) Pub. Date: Nov. 2, 2017

(54) Graphene Based Conformal Heat Sink and Method Therefor

(71) Applicant: DELL PRODUCTS, LP, Round Rock, TX (US)

(72) Inventors: Christopher A. Torres, San Marcos, TX (US); Travis Christian North, Cedar Park, TX (US); Deeder M. Aurgonzeb, Austin, TX (US)

(21) Appl. No.: 15/140,981

(22) Filed: Apr. 28, 2016

(51) Int. Cl. G06F 1/20; H05K 1/02; H05K 7/20; H05K 1/18; H05K 3/28

(52) U.S. Cl. CPC G06F 1/20; H05K 1/181; H05K 3/285; H05K 7/20518; H05K 1/0203; H05K 2201/06; H05K 2203/0736; H05K 2203/12; H05K 2203/163; H05K 2201/05

(57) ABSTRACT

An information handling system includes an electronic assembly, the assembly including heat-generating components arranged on a printed circuit board. The system further includes a conformal coating that is applied over a first region of the electronic assembly. The coating includes a graphene containing polymer material configured to dissipate heat away from the heat-generating components.

### FIELD OF THE DISCLOSURE

This disclosure relates generally to information handling systems, and more particularly relates to a graphene based conformal heat sink.

### BACKGROUND

As the value and use of information continues to increase, individuals and businesses seek additional ways to process and store information. One option is an information handling system. An information handling system generally processes, compiles, stores, and/or communicates information or data for business, personal, or other purposes. Because technology and information handling needs and requirements can vary between different applications, information handling systems can also vary regarding what information is handled, how the information is handled, how much information is processed, stored, or communicated, and how quickly and efficiently the information can be processed, stored, or communicated. The variations in information handling systems allow for information handling systems to be general or configured for a specific user or specific use such as financial transaction processing, airline reservations, enterprise data storage, or global communications. In addition, information handling systems can include a variety of hardware and software components that can be configured to process, store, and communicate information and can include one or more computer systems, data storage systems, and networking systems.

### SUMMARY

An information handling system includes an electronic assembly, the assembly including heat-generating components arranged on a printed circuit board. The system further includes a conformal coating that is applied over a first region of the electronic assembly. The coating includes a graphene containing polymer material configured to dissipate heat away from the heat-generating components.

### BRIEF DESCRIPTION OF THE DRAWINGS

Embodiments incorporating teachings of the present disclosure are shown and described with respect to the drawings presented herein, in which:

FIG. 1 is a cross sectional view of an electronic assembly with a conformal graphene-containing polymer film according to a specific embodiment of the present disclosure;

FIG. 2 is a cross sectional view of an electronic assembly with a conformal graphene-containing polymer film optimized for disparate regions according to a specific embodiment of the present disclosure;

FIG. 3 is a cross sectional view of an electronic assembly with a conformal graphene-containing polymer film to provide a thermal gap pad according to a specific embodiment of the present disclosure;

FIG. 4 is a cross sectional view of an electronic assembly with a conformal graphene-containing polymer film having increased surface area according to a specific embodiment of the present disclosure;

FIG. 5 is a cross sectional view of an electronic assembly with a conformal graphene-containing polymer film and an underlying electrical insulating film according to a specific embodiment of the present disclosure;

FIG. 6 is a cross sectional view of the conformal graphene-containing polymer film of FIGS. 1-5 according to a specific embodiments of the present disclosure;

FIG. 7 is a flow diagram illustrating a method for applying a graphene-containing polymer conformal coating to an information handling system according to a specific embodiment of the present disclosure;

FIG. 8 is a flow diagram illustrating another method for applying a graphene-containing polymer conformal coating to an information handling system according to a specific embodiment of the present disclosure; and

FIG. 9 is a block diagram illustrating an information handling system in accordance with a specific embodiment of the present disclosure.

### DETAILED DESCRIPTION OF DRAWINGS

The following description in combination with the Figures is provided to assist in understanding the teachings disclosed herein. The following discussion will focus on specific implementations and embodiments of the teachings. This focus is provided to assist in describing the teachings and should not be interpreted as a limitation on the scope or applicability of the teachings. However, other teachings certainly can be utilized in this application.

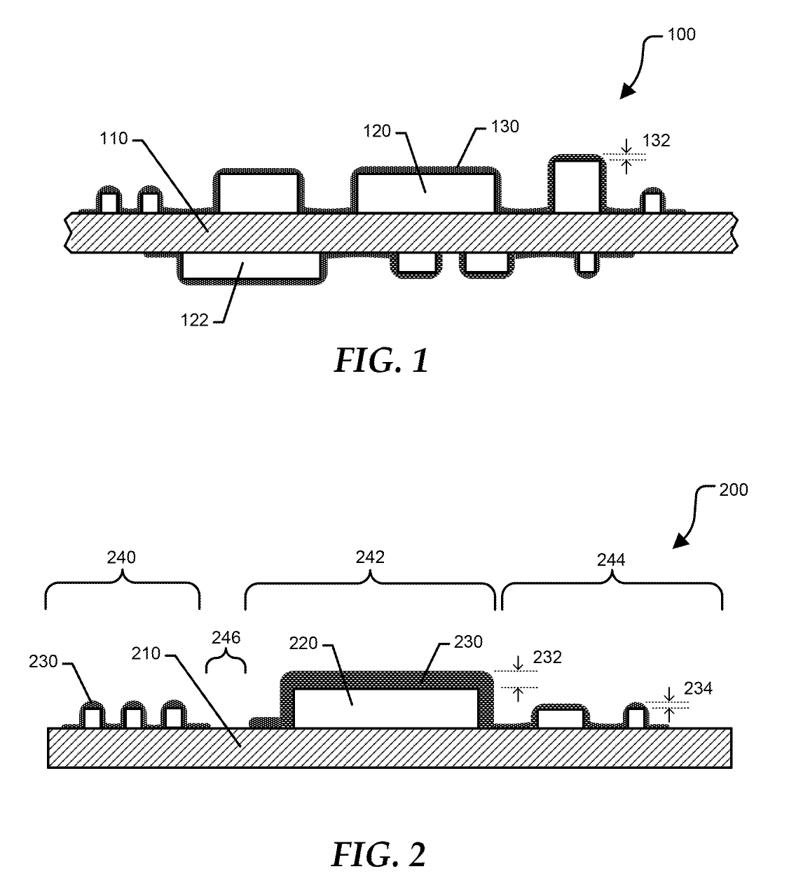

An information handling system includes one or more electronic components, such as integrated circuits. During operation, the electronic components generate heat, which must be dissipated from the components to optimize performance and reliability of the information handling system. For example, the operating frequency of a central processing unit (CPU) is significantly limited if heat generated by the device is not removed. Accordingly, heat sinks, heat pipes, forced air circulation, and other techniques are used to transfer heat away from the heat generating components. FIGS. 1-9 illustrate techniques for applying a graphene-containing polymer over the surface of an electronic assembly. The polymer provides efficient transfer of heat away from the heat generating components. The polymer also provides a large surface area, thereby increasing the efficiency at which heat can be dissipated into the environment. Properties of the graphene-containing polymer can be manipulated to provide desired heat transfer characteristics. For example, heat transfer efficiency can be adjusted by varying an amount of graphene included in the polymer, by adjusting the thickness of the polymer layer, and by varying the size and shape of the graphene particles suspended with the polymer. The direction of heat transfer within the graphene-containing polymer can be regulated by controlling the orientation of graphene particles within the polymer. The film can be applied by spraying, molding, vapor deposition, an automated dispensing nozzle, and the like. The film can also provide a barrier preventing moisture from contacting the electronic components.

FIG. 1 shows an electronic assembly 100 with a conformal graphene-containing polymer. Electronic assembly 100 includes a printed circuit board (PCB) 110, one or more electronic components 120, and a conformal graphene-containing polymer 130. A thickness of the polymer coating is indicated by reference 132. PCB 100 can include a fiberglass reinforced epoxy laminate, such as FR-4, or another material. Electronic components 120 can include CPUs, integrated chipsets, memory devices, power regulation devices, discrete components, and the like. Components 120 are typically soldered to metal pads and interconnects patterned on the surface of PCB 110. As shown, components 120 can be mounted on both surfaces of PCB 110. Graphene containing polymer film can be applied to a desired portion of either surface of electronic assembly 100, or can be applied to the entirety of one or more surfaces of assembly 100. Polymer 130 can be applied in an uncured state, and can be subsequently cured to provide a flexible or rigid coating. For example polymer 130 can be applied in a semi-viscous liquid state, and can be cured using heat, ultra-violet light, a chemical hardener, and the like. Thickness 132 of polymer 130 may vary from approximately 10 microns to in excess of 100 microns.

The formulation of graphene-containing polymer 130 can be adjusted to optimize one or more thermal, electrical, mechanical, and other characteristics, or can be adjusted to provide an optimal compromise between multiple characteristics. The loading of graphene in the polymer can be varied based on a desired level of thermal conductivity. For example, graphene-containing polymer can include between 10% and 80% graphene, expressed as a weight-percentage of graphene relative to the total weight of graphene and polymer. A specific polymer can be selected based on its thermal emissivity properties. A high-emissivity material is better able to radiate heat into the environment. The polymer included in graphene-containing polymer 130 can be urethane, acrylate, or another polymer having desired chemical, electrical, thermal, and mechanical properties.

A higher loading of graphene in graphene-containing polymer 130 can provide increased thermal conductivity, however high loading levels may increase the electrical conductivity of the polymer, which can be undesirable. Higher loading of graphene can reduce the viscosity of the uncured material, which may impact how readily the material conforms to the surfaces of PCB 110 and components 120 of electronic assembly 100. Higher loading of graphene may impact how well the polymer hermetically seals assembly 100 against moisture. The viscosity of the uncured polymer 130 can affect a coating thickness, depending on the specific application method employed.

Graphene-containing polymer 130 can be applied by spraying, molding, vapor deposition, by an automated dispensing nozzle, or by another manufacturing process suitable for polymer fabrication. One or more application techniques can be selected based on desired thermal and mechanical properties of the polymer layer. Application of multiple coats of polymer 130 can be used to increase thickness 132 of the coating, thereby increasing the thermal conductivity of polymer 130. The application technique can impact alignment of graphene particles within the polymer carrier, thereby determining how heat is transferred in different directions by the polymer.

Graphene-containing polymer 130 can be formulated to remain flexible or stretchable after being cured, thereby facilitating use as a heat spreader in an apparatus that is flexible, such as a flexible printed circuit boards, flexible graphic display devices, and the like. Polymer formulations can be optimized for compressibility as well as self-healing, adhesive, and cohesive properties. A conformal graphene-containing polymer heatsink or heat spreader is ideal for use in flexible devices. A self-healing polymer is capable of healing cracks that can develop in the coating due to repeated flexing. The polymer can exhibit self-healing at room temperature and/or in response to heat generated during operation of electronic assembly 100. The polymer material can provide a barrier, protecting an information handling system from corrosion caused by chemicals or moisture. The material can be engineered to be substantially hydrophobic. FIGS. 2-6, below, illustrate techniques for manipulating properties of graphene-containing polymer 130.

FIG. 2 shows an electronic assembly 200 with a conformal graphene-containing polymer optimized for disparate regions according to a specific embodiment of the present disclosure. Assembly 200 is similar to assembly 100 of FIG. 1, including a PCB 210, electronic components 220, and a graphene-containing polymer 230. FIG. 2 illustrates how a thickness of the applied polymer can be varied across regions of assembly 200 to provide individualized thermal dissipation properties. For example, a thickness of the polymer coating in area 242, indicated by reference 232, is thicker than the coating thickness in areas 240 and 244, indicated by reference 234. A metering dispensing system can be used to vary the properties of polymer 230 in different areas of the information handling system. For example, the thickness of polymer 330 on hotter components, such as CPUs and power regulation circuits, can be greater than 100 microns, while the thickness on another portion of assembly 200 can be 10-100 microns. Multiple applications can be applied to increase the thickness, or a polymer formulation with a different viscosity can be used. Discontinuities in polymer layer 230, such as at gap 246, can be used to isolate thermally disparate regions.

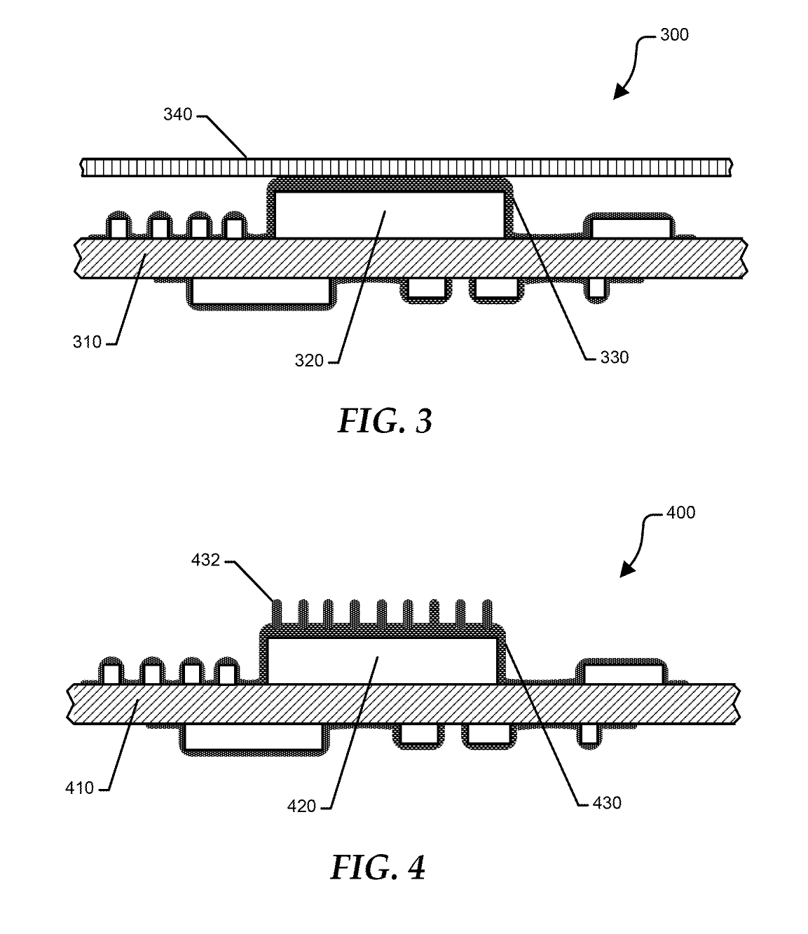

FIG. 3 shows an electronic assembly 300 with a conformal graphene-containing polymer to provide a thermal gap pad according to a specific embodiment of the present disclosure. Assembly 300 is similar to assembly 100 of FIG. 1, including a PCB 310, electronic components 320, and a graphene-containing polymer 330. Assembly 340 also includes a shield 340, such as a metal skin, heat sink, liquid radiator, or heat spreader. Polymer 330 that is sandwiched between component 320 and shield 340 can conduct heat generated by component 320 to shield 340, much like a thermal paste provides.

FIG. 4 shows an electronic assembly 400 with a conformal graphene-containing polymer having increased surface area according to a specific embodiment of the present disclosure. Assembly 400 is again similar to assembly 100 of FIG. 1, including a PCB 410, electronic components 420, and a graphene-containing polymer 430. Assembly 400 also includes fin structures 432 that serve to increase the surface area of the heat-radiating polymer 430. Heat transfer is proportional to the surface area of the radiating body, polymer 430. A three-dimensional fin array can be created by layering ribs over a base coat of polymer 430. For example, ribs can be added via an automated dispensing nozzle. Alternatively, a silicone mold or a mask can be used to fabricate or pattern fins 432. Fins 432 can be parallel ridges, individual post-like nubs, or another geometry that provides greater surface area relative to a flat surface.

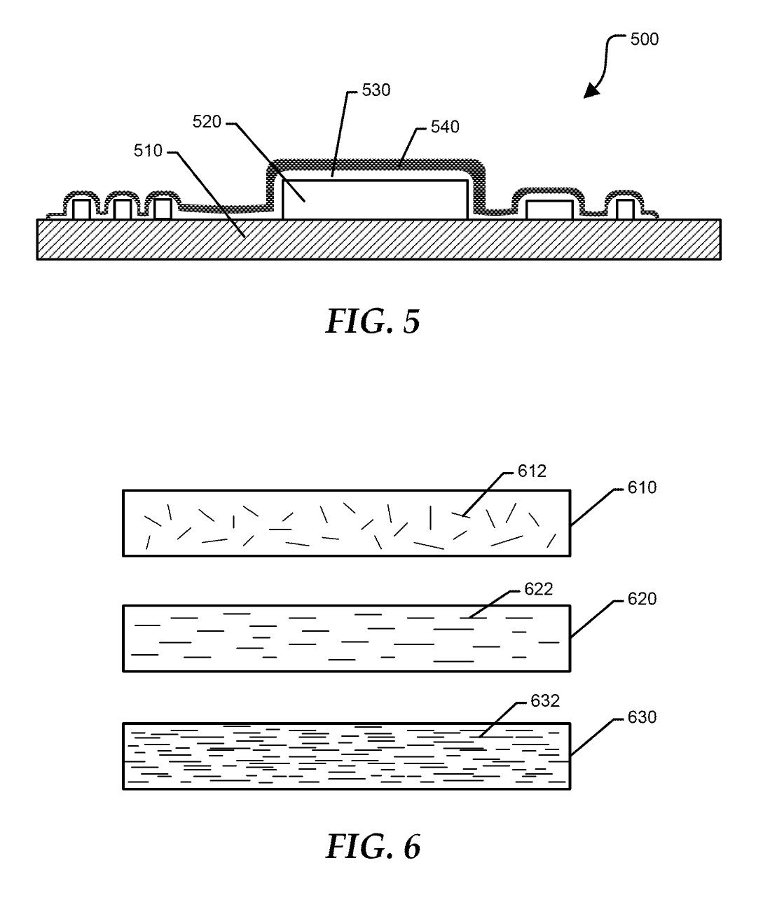

FIG. 5 shows an electronic assembly 500 with a conformal graphene-containing polymer film and an underlying electrical insulating film according to a specific embodiment of the present disclosure. Assembly 500 includes a PCB 510, electronic components 520, a layer of polymer 430 that does not include graphene, and a graphene-containing polymer 540. Polymer 530 can provide an electrically insulating layer between signal pins and traces of PCB 510 and components 520, and graphene-containing polymer 540. Graphene-containing polymer 540 can include a high loading of graphene in order to maximize its heat conducting properties. However, such high loading can potentially render the material conductive, which could result in a short-circuit between signal nodes of assembly 500 as current passes through layer 540. Graphene-free polymer 530 can be applied to assembly 500 before application of graphene-containing polymer 540, thus insulating the circuitry from layer 540. Graphene-free polymer 530 can be thin so as not to significantly impede transfer of heat from components 520 to graphene-containing polymer 540. Furthermore, the graphene loading of polymer 540 can be very high, improving its heat transfer efficiency. Graphene-free polymer 530 can serve to enhance adhesion of layer 540 to apparatus 500.

FIG. 6 shows side views 610, 620, and 630 of the conformal graphene-containing polymer of FIGS. 1-5 according to specific embodiments of the present disclosure. Cross section 610 illustrates a polymer including a moderate loading of unaligned graphene 612. Graphene 612 can include flakes or elongated clusters of graphene. For example, a particle of graphene 612 may range from a few microns to approximately 100 microns in length, while the width may be up to approximately 5 microns. Longer particles generally provide better heat conduction. The random orientation of particles of graphene 612 can provide substantially omnidirectional heat transfer, for example parallel and perpendicular to the major surfaces of the polymer layer. Some application techniques, such as employing turbulent ducting of the uncured polymer material, can favor a random orientation of graphene particles within the polymer.

Cross section 620 illustrates a polymer including a moderate loading of graphene, wherein the individual particles of graphene are substantially aligned parallel to the major surfaces of the polymer layer. This arrangement of particles can greatly accentuate orthotropic heat transfer in the direction of the plane of the polymer layer compared to heat transfer perpendicular to the layer. With the particles of graphene substantially aligned, heat transfer in a direction parallel to the major surfaced of the polymer layer can meet or exceed 40 watts per meter-Kelvin.

Cross section 630 illustrates a polymer including a high loading of graphene, and wherein the individual particles of graphene are substantially aligned parallel to the major surfaces of the polymer layer. This material would be expected to provide relatively higher thermal conductivity compared to the material cross sections 610 and 620. Like cross section 620, the material provides substantially orthotropic heat transfer in the direction of the plane of the polymer layer. As described above with reference to FIG. 5, an intermediate layer of graphene-free polymer can prevent leakage or short circuiting through the heavily loaded graphene-containing polymer.

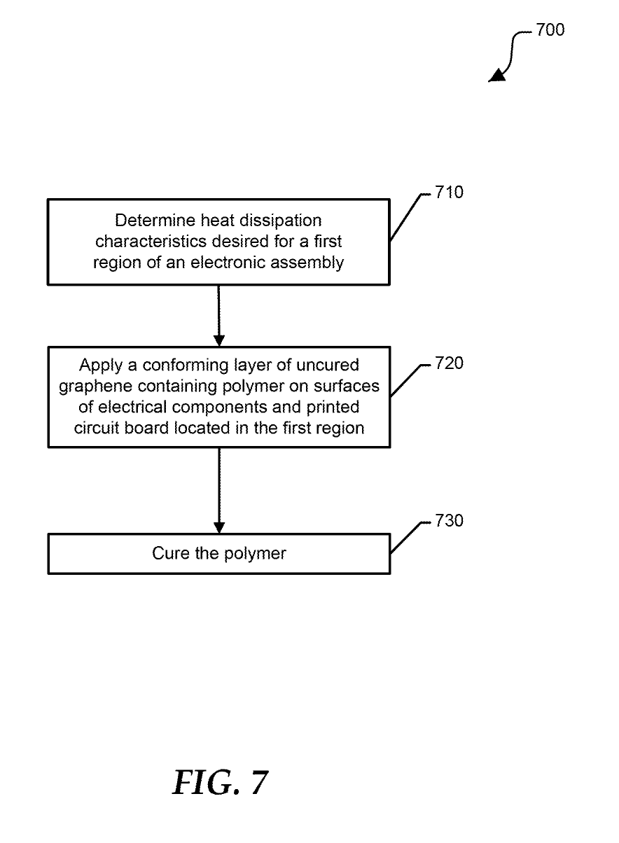

FIG. 7 is a flow diagram illustrating a method 700 for applying a graphene-containing polymer conformal coating to an information handling system according to a specific embodiment of the present disclosure. Method 700 begins at block 710 where desired heat dissipation characteristics are determined for a first region of an electronic assembly. For example, it may be desirable to spread heat generated by a CPU disposed at a laptop computer main-board over a large portion of the board. The method continues at block 720 where a conforming layer of uncured graphene-containing polymer is applied on surfaces of electronic components and an associated printed circuit board located in the first region. Method 700 completes at block 730 where the graphene-containing polymer is cured, for example by application of heat.

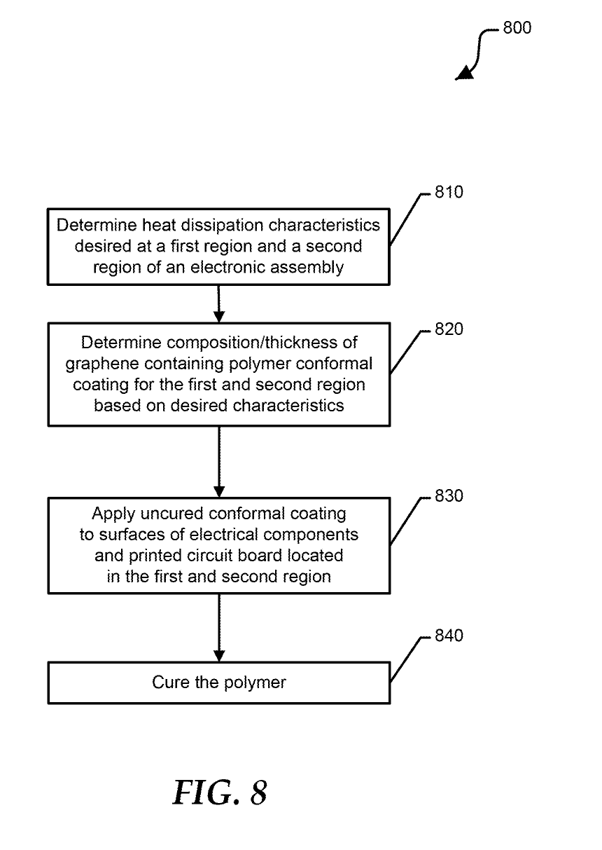

FIG. 8 is a flow diagram illustrating another method 800 for applying a graphene-containing polymer conformal coating to an information handling system according to a specific embodiment of the present disclosure. Method 800 begins at block 810 where desired heat dissipation characteristics are determined for a first region and a second region of an electronic assembly. For example, a large degree of heat transfer may be desired at a region including a CPU, while other areas including a chipset device requires a lesser degree of heat transfer. Method 800 proceeds to block 820 where a composition and thickness of a graphene-containing polymer conformal coating is determined for the first and second regions based on the desired characteristics. For example, it may be determined that a thick layer of polymer having a high graphene loading be applied to a large region surrounding the CPU, while a thinner layer of polymer having moderate graphene loading be applied to a region including the chipset devices. Other determinations include identifying a desired degree of orthotropic heat transfer for each region, whether an intermediate coating of graphene-free polymer is indicated, and other characteristics described above. The method continues at block 830 where a conforming layer of uncured graphene-containing polymer is applied on surfaces of electronic components and an associated printed circuit board located in the first and second regions. Method 800 completes at block 840 where the graphene-containing polymer is cured.

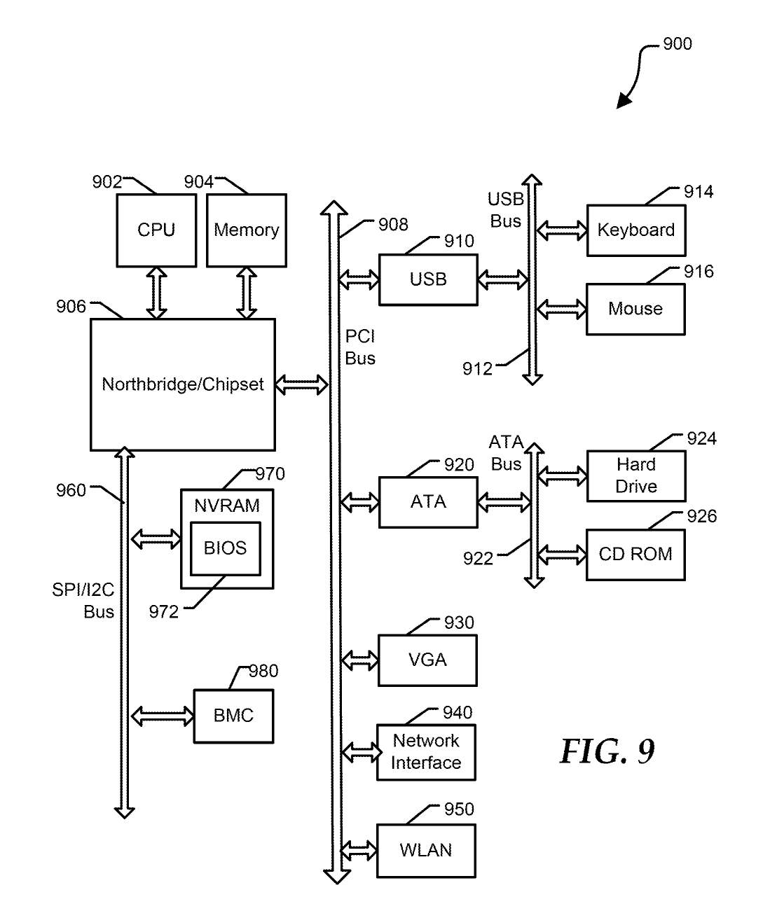

FIG. 9 shows an information handling system 900 including a processor 902, a memory 904, a northbridge/chipset 906, a PCI bus 908, a universal serial bus (USB) controller 910, a USB 912, a keyboard device controller 914, a mouse device controller 916, a configuration an ATA bus controller 920, an ATA bus 922, a hard drive device controller 924, a compact disk read only memory (CD ROM) device controller 926, a video graphics array (VGA) device controller 930, a network interface controller (NIC) 940, a wireless local area network (WLAN) controller 950, a serial peripheral interface (SPI) bus 960, a NVRAM 970 for storing BIOS 972, and a baseboard management controller (BMC) 980. BMC 980 can be referred to as a service processor or embedded controller (EC). Capabilities and functions provided by BMC 980 can vary considerably based on the type of information handling system. For example, the term baseboard management system is often used to describe an embedded processor included at a server, while an embedded controller is more likely to be found in a consumer-level device. As disclosed herein, BMC 980 represents a processing device different from CPU 902, which provides various management functions for information handling system 900. For example, an embedded controller may be responsible for power management, cooling management, and the like. An embedded controller included at a data storage system can be referred to as a storage enclosure processor.

For purpose of this disclosure information handling system 900 can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 900 can be a personal computer, a laptop computer, a smart phone, a tablet device or other consumer electronic device, a network server, a network storage device, a switch, a router, or another network communication device, or any other suitable device and may vary in size, shape, performance, functionality, and price. Further, information handling system 900 can include processing resources for executing machine-executable code, such as CPU 902, a programmable logic array (PLA), an embedded device such as a System-on-a-Chip (SoC), or other control logic hardware. Information handling system 900 can also include one or more computer-readable medium for storing machine-executable code, such as software or data.

System 900 can include additional processors (not shown at FIG. 1) that are configured to provide localized or specific control functions, such as a battery management controller. Bus 960 can include one or more busses, including a SPI bus, an I2C bus, a system management bus (SMBUS), a power management bus (PMBUS), and the like. BMC 980 can be configured to provide out-of-band access to devices at information handling system 900. As used herein, out-of-band access herein refers to operations performed prior to execution of BIOS 972 by processor 902 to initialize operation of system 900.

BIOS 972 can be referred to as a firmware image, and the term BIOS is herein used interchangeably with the term firmware image, or simply firmware. BIOS 972 includes instructions executable by CPU 902 to initialize and test the hardware components of system 900, and to load a boot loader or an operating system (OS) from a mass storage device. BIOS 972 additionally provides an abstraction layer for the hardware, i.e. a consistent way for application programs and operating systems to interact with the keyboard, display, and other input/output devices. When power is first applied to information handling system 900, the system begins a sequence of initialization procedures. During the initialization sequence, also referred to as a boot sequence, components of system 900 are configured and enabled for operation, and device drivers can be installed. Device drivers provide an interface through which other components of the system 900 can communicate with a corresponding device.

Information handling system 900 can include additional components and additional busses, not shown for clarity. For example, system 900 can include multiple processor cores, audio devices, and the like. While a particular arrangement of bus technologies and interconnections is illustrated for the purpose of example, one of skill will appreciate that the techniques disclosed herein are applicable to other system architectures. System 900 can include multiple CPUs and redundant bus controllers. One or more components can be integrated together. For example, portions of northbridge/chipset 906 can be integrated within CPU 902. Additional components of information handling system 900 can include one or more storage devices that can store machine-executable code, one or more communications ports for communicating with external devices, and the like. An example of information handling system 900 includes a multi-tenant chassis system where groups of tenants (users) share a common chassis, and each of the tenants has a unique set of resources assigned to them. The resources can include blade servers of the chassis, input/output (I/O) modules, Peripheral Component Interconnect-Express (PCIe) cards, storage controllers, and the like.

Information handling system 900 can include a set of instructions that can be executed to cause the information handling system to perform any one or more of the methods or computer based functions disclosed herein. The information handling system 900 may operate as a standalone device or may be connected to other computer systems or peripheral devices, such as by a network. In a networked deployment, the information handling system 900 may operate in the capacity of a server or as a client user computer in a server-client user network environment, or as a peer computer system in a peer-to-peer (or distributed) network environment. The information handling system 900 can also be implemented as or incorporated into various devices, such as a personal computer (PC), a tablet PC, a set-top box (STB), a personal digital assistant (PDA), a mobile device, a palmtop computer, a laptop computer, a desktop computer, a communications device, a wireless telephone, a land-line telephone, a control system, a camera, a scanner, a facsimile machine, a printer, a pager, a personal trusted device, a web appliance, a network router, switch or bridge, or any other machine capable of executing a set of instructions (sequential or otherwise) that specify actions to be taken by that machine. In a particular embodiment, the computer system 900 can be implemented using electronic devices that provide voice, video or data communication. Further, while a single information handling system 900 is illustrated, the term “system” shall also be taken to include any collection of systems or sub-systems that individually or jointly execute a set, or multiple sets, of instructions to perform one or more computer functions.

The information handling system 900 can include a disk drive unit and may include a computer-readable medium, not shown in FIG. 9, in which one or more sets of instructions, such as software, can be embedded. Further, the instructions may embody one or more of the methods or logic as described herein. In a particular embodiment, the instructions may reside completely, or at least partially, within system memory 904 or another memory included at system 900, and/or within the processor 902 during execution by the information handling system 900. The system memory 904 and the processor 902 also may include computer-readable media.

In an alternative embodiment, dedicated hardware implementations such as application specific integrated circuits, programmable logic arrays and other hardware devices can be constructed to implement one or more of the methods described herein. Applications that may include the apparatus and systems of various embodiments can broadly include a variety of electronic and computer systems. One or more embodiments described herein may implement functions using two or more specific interconnected hardware modules or devices with related control and data signals that can be communicated between and through the modules, or as portions of an application-specific integrated circuit. Accordingly, the present system encompasses software, firmware, and hardware implementations.

In accordance with various embodiments of the present disclosure, the methods described herein may be implemented by software programs executable by a computer system. Further, in an exemplary, non-limited embodiment, implementations can include distributed processing, component/object distributed processing, and parallel processing. Alternatively, virtual computer system processing can be constructed to implement one or more of the methods or functionality as described herein.

The present disclosure contemplates a computer-readable medium that includes instructions or receives and executes instructions responsive to a propagated signal; so that a device connected to a network can communicate voice, video or data over the network. Further, the instructions may be transmitted or received over the network via the network interface device.

While the computer-readable medium is shown to be a single medium, the term “computer-readable medium” includes a single medium or multiple media, such as a centralized or distributed database, and/or associated caches and servers that store one or more sets of instructions. The term “computer-readable medium” shall also include any medium that is capable of storing, encoding or carrying a set of instructions for execution by a processor or that cause a computer system to perform any one or more of the methods or operations disclosed herein.

In a particular non-limiting, exemplary embodiment, the computer-readable medium can include a solid-state memory such as a memory card or other package that houses one or more non-volatile read-only memories.

Further, the computer-readable medium can be a random access memory or other volatile re-writable memory. Additionally, the computer-readable medium can include a magneto-optical or optical medium, such as a disk or tapes or other storage device to store information received via carrier wave signals such as a signal communicated over a transmission medium. A digital file attachment to an e-mail or other self-contained information archive or set of archives may be considered a distribution medium that is equivalent to a tangible storage medium. Accordingly, the disclosure is considered to include any one or more of a computer-readable medium or a distribution medium and other equivalents and successor media, in which data or instructions may be stored.

Although only a few exemplary embodiments have been described in detail above, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

1. A method comprising:
determining heat dissipation characteristics desired at a first region of an electronic assembly;
applying a conforming layer of uncured graphene having polymer material to surfaces of electrical components and printed circuit board located in the first region; and
curing the polymer material.

2. The method of claim 1, further comprising determining a desired thickness of the uncured graphene having polymer material based on the desired heat dissipation characteristics.

3. The method of claim 1, further comprising determining a percent-loading of graphene of the applied polymer material based on the desired heat dissipation characteristics.

4. The method of claim 1, further comprising applying an electrically insulating polymer layer to the first region before applying the uncured graphene having polymer material.

5. The method of claim 1, wherein the uncured graphene having polymer material is applied by spraying.

6. The method of claim 1, wherein the uncured graphene having polymer material is applied by an automated dispensing nozzle.

7. The method of claim 1, wherein the uncured graphene having polymer material is applied using an injection mold.

8. The method of claim 1, wherein the cured graphene having polymer material provides orthotropic heat transfer characteristics.

9. The method of claim 1, wherein the cured graphene having polymer material provides omnidirectional heat transfer characteristics.

10. The method of claim 1, wherein a thickness of the applied uncured graphene having polymer material is between five and two hundred microns.

11. The method of claim 1, wherein the uncured graphene having polymer material is applied to form a plurality of features protruding outward from the surfaces of the electronic assembly to increase a surface area of the material.

12. The method of claim 1, further comprising:
determining heat dissipation characteristics desired at a second region of the electronic assembly; and
applying a conforming layer of uncured graphene having polymer material to surfaces of electrical components and printed circuit board located in the second region, the material at the second region having heat dissipating characteristics different than the material at the first region.

13. An information handling system comprising:
an electronic assembly including heat-generating components arranged on a printed circuit board; and
a conformal coating applied over a first region of the electronic assembly, the coating including a graphene and polymer material configured to dissipate heat away from the heat-generating components.

14. The system of claim 13, wherein a thickness of the conformal coating is determined based on desired heat dissipation characteristics.

15. The system of claim 13, wherein a percent-loading of graphene of the conformal coating is determined based on desired heat dissipation characteristics.

16. The system of claim 13, further comprising:
a second conformal coating applied to the first region of the electronic assembly, the second conformal coating including an insulating polymer material in direct contact with the electronic assembly and located between the electronic assembly and the first conformal coating.

17. The system of claim 13, wherein the conformal coating provides orthotropic heat transfer characteristics.

18. The system of claim 13, wherein the conformal coating provides omnidirectional heat transfer characteristics.

19. The system of claim 13, wherein the printed circuit board and the conformal coating are flexible

20. The system of claim 13, wherein conformal coating includes a plurality of features protruding outward from the surfaces of the electronic assembly to increase a surface area of the conformal coating.
